(19) United States
(12) Patent Application Publication
(10) Pub. No.: US 2014/0203273 A1
(43) Pub. Date: Jul. 24, 2014

(54) ORGANIC ELECTROLUMINESCENCE ELEMENT

(71) Applicant: PANASONIC CORPORATION, Osaka (JP)

(72) Inventor: Hirofumi Kubota, Osaka (JP)

(73) Assignee: PANASONIC CORPORATION, Osaka (JP)

(21) Appl. No.: 14/342,772

(22) PCT Filed: Sep. 20, 2012
(86) PCT No.: PCT/JP2012/074107

§ 371 Date: Mar. 4, 2014

(30) Foreign Application Priority Data
Sep. 21, 2011 (JP) 2011-205684

(51) Int. Cl. H01L 51/52; H01L 51/50

(52) U.S. Cl. CPC H01L 51/5268; H01L 51/5012
USPC 257/40

(57) ABSTRACT

The present invention relates to an organic electroluminescence element including a transparent electrode, a light-reflective electrode, and an organic layer including a light-emitting layer and being between the transparent electrode and the light-reflective electrode. The organic layer includes a scattering layer for scattering light from the light-emitting layer. A standing wave results from interference of the light from the light-emitting layer. A center position of a thickness of the scattering layer is at a particular position. A maximum intensity of the standing wave at the particular position is 80% or more of a peak value of an intensity of the standing wave.

### TECHNICAL FIELD

The present invention relates to organic electroluminescence elements.

### BACKGROUND ART

Recently, organic electroluminescence elements have been developed for application to an illumination panel and the like. In the organic electroluminescence element, when a voltage is applied between an anode and a cathode, light is produced by a light-emitting layer and emitted to an outside via a transparent electrode. Generally, produced light may be absorbed by the organic layer and the substrate and may be lost in total reflection at interfaces, and this causes a decrease in an amount of light. Hence, an amount of light emitted outside is less than an amount of light produced in the light-emitting layer. Therefore, improvement of the light-outcoupling efficiency to achieve higher luminance is one of problem to be solved in the field of the organic electroluminescence elements.

For example, JP 2006-286616 A (hereafter, referred to as Patent Document 1) discloses a technique of providing the light-scattering layer outside the electrodes present on the opposite sides of the light-emitting layer to improve the light-outcoupling efficiency in order to achieve higher luminance. The light-scattering layer may be formed by application of a material with a different refractive index. Specifically, as the light-scattering layer, WO 2009/060916 A1 (hereafter, referred to as Patent Document 2) discloses a scattering layer made of glass containing a plurality of scattering materials.

In a case where the light-scattering layer is used for improving light-outcoupling efficiency, it is important to enhance scattering properties of the light-scattering layer. In other words, it is important to optimize the scattering properties of the light-scattering layer. In the past, in order to enhance scattering properties, configuration of the light-scattering layer itself (i.e., characteristics of materials and a shape of the surface or the inside) has been modified. For example, in Patent Document 1, the light-scattering layer is formed by application of a material having a different refractive index, and an interface of material inside the light-scattering layer causes light scattering. Besides, in Patent Document 2, to improve the scattering properties, a refractive index distribution in the light-scattering layer and a wavy structure on the surface thereof are optimized

However, a conventional method such as a method of forming the light-scattering layer outside the electrode may be insufficient to improve light-outcoupling efficiency. Accordingly, further improvement on light-outcoupling efficiency is required. Moreover, in a case where the light-scattering layer is formed outside the electrode, the manufacturing process is troublesome. Additionally, a quality of the electrode formed on the light scattering layer may be deteriorated, and thus electrical stability may be poor.

### SUMMARY OF INVENTION

The present invention has been made in view of the above circumstances, and the object thereof is to provide an organic electroluminescence element with excellent light-outcoupling efficiency.

According to a first aspect of the present invention, there is provided an organic electroluminescence element including: a transparent electrode; a light-reflective electrode; and an organic layer including a light-emitting layer and being between the transparent electrode and the light-reflective electrode, wherein: the organic layer further includes a scattering layer for scattering light from the light-emitting layer; a standing wave results from interference of the light from the light-emitting layer; a center position of a thickness of the scattering layer is at a particular position; and a maximum intensity of the standing wave at the particular position is 80% or more of a peak value of an intensity the standing wave.

According to a second aspect of the present invention, there is provided an organic electroluminescence element in which the scattering layer is between the light-emitting layer and the light-reflective electrode, the organic electroluminescence element being in accordance with the first aspect.

According to a third aspect of the present invention, there is provided an organic electroluminescence element in which the scattering layer is between the light-emitting layer and the transparent electrode, the organic electroluminescence element being in accordance with the first aspect.

According to a fourth aspect of the present invention, there is provided an organic electroluminescence element in which: the organic layer includes a plurality of the light-emitting layers and an interlayer between the plurality of the light-emitting layers; and the interlayer includes the scattering layer, the organic electroluminescence element being in accordance with the first aspect.

According to a fifth aspect of the present invention, there is provided an organic electroluminescence element in which the standing wave of the light from the light-emitting layer has a node at the light-reflective electrode, the organic electroluminescence element being in accordance with any one of the first to fourth aspects.

According to a sixth aspect of the present invention, there is provided an organic electroluminescence element in which: the organic layer includes a green light-emitting layer and the scattering layer; and a distance between the scattering layer and the light-reflective electrode falls within a range of 60 nm to 95 nm, the organic electroluminescence element being in accordance with any one of the first to fifth aspects.

According to a seventh aspect of the present invention, there is provided an organic electroluminescence element in which: the organic layer includes a green light-emitting layer and the scattering layer; and a distance between the scattering layer and the light-reflective electrode falls within a range of 190 nm to 280 nm, the organic electroluminescence element being in accordance with any one of the first to fifth aspects.

According to the present invention, a scattering layer is at a position corresponding to an anti-node of a standing wave caused by interference, and therefore it is possible to enhance a scattering intensity of light that is intensified by interference, and to obtain an organic electroluminescence element with excellent light-outcoupling efficiency.

### BRIEF DESCRIPTION OF DRAWINGS

FIG. 1 is a cross-section illustrating an embodiment of the organic electroluminescence element;

FIG. 2 is a cross-section illustrating another embodiment of the organic electroluminescence element;

FIG. 3 is a cross-section illustrating another embodiment of the organic electroluminescence element;

FIG. 4 is a cross-section illustrating another embodiment of the organic electroluminescence element;

FIG. 5 is a cross-section illustrating another embodiment of the organic electroluminescence element; and

FIG. 6 is a graph showing properties of a luminosity function.

### DESCRIPTION OF EMBODIMENTS

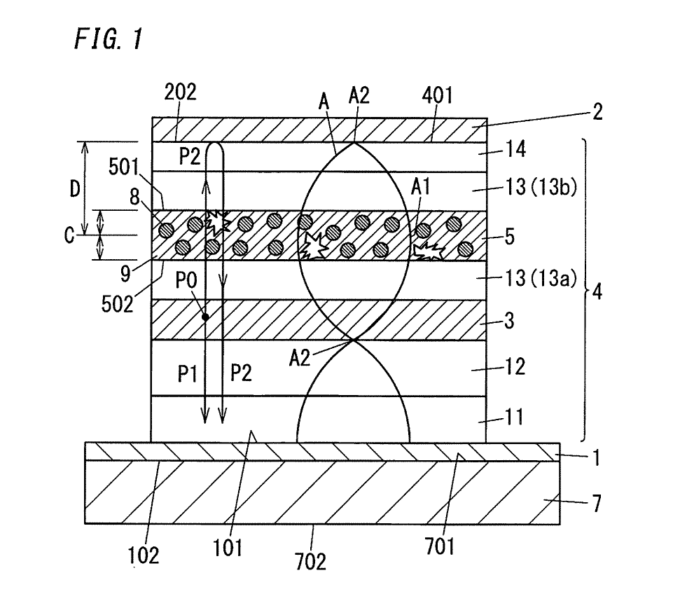

FIG. 1 shows an example of an embodiment of an organic electroluminescence element. The organic electroluminescence element includes an organic layer 4 existing between a transparent electrode 1 and a light-reflective electrode 2. The organic layer 4 includes a light-emitting layer 3. In the present embodiment of the organic electroluminescence element, a substrate 7 is provided on an opposite face (a second surface of the transparent electrode 1) 102 of the transparent electrode 1 from the organic layer 4. This organic electroluminescence element may be prepared by forming the transparent electrode 1 on a surface 701 of the substrate 7, subsequently stacking layers of the organic layer 4 on a surface (a first surface of the transparent electrode 1) 101 of the transparent electrode 1, and thereafter disposing the light-reflective electrode 2 on an uppermost face 401 of the organic layer 4. Since the substrate 7 is a transparent substrate, light generated in the light-emitting layer 3 is transmitted by the transparent electrode 1 and the substrate 7 and is emitted outside via the substrate 7. In brief, the organic electroluminescence element shown in FIG. 1 has a bottom emission structure. Note that, not shown in FIG. 1, this organic electroluminescence element includes a sealing member (e.g., a drying agent and a facing substrate) which is over the light-reflective electrode 2 to cover it.

The substrate 7 is made of appropriate material so long as the substrate 7 is a transparent substrate. For example, the substrate 7 may be a glass substrate or a resin substrate. As a modification of the structure shown in FIG. 1, the light-reflective electrode 2 of FIG. 1 may be replaced with another transparent electrode 1 having light transmissive or semi-transmissive properties, and the transparent electrode 1 of FIG. 1 may be replaced with another light-reflective electrode 2. In this modification, the transparent electrode 1 may be an uppermost layer, and the light-reflective electrode 2 may be between this transparent electrode 1 and the substrate 7. In other words, the light-reflective electrode 2 is on the surface (the first surface of the substrate 7) 701 of the substrate 7, the organic layer 4 is on this light-reflective electrode 2, and the transparent electrode 1 is on the uppermost face 401 of the organic layer 4. In this modification, the organic electroluminescence element with a top emission structure is obtained. In addition, when the light-reflective electrode 2 is substituted by a transparent electrode, a transparent organic electroluminescence element may be obtained.

The transparent electrode 1 is normally an electrode that functions as an anode. The light-reflective electrode 2 is normally an electrode that functions as a cathode. The organic layer 4 is a layer between the transparent electrode 1 and the light-reflective electrode 2, which are paired electrodes.

The organic layer 4 includes the light-emitting layer 3 at least. Normally, in order to allow the light-emitting layer 3 to produce light, the organic layer 4 includes layers with charge injection properties and charge transport properties. As the layers with such properties, a hole-injection layer 11, a hole-transport layer 12, an electron-transport layer 13, and an electron-injection layer 14 are provided.

Moreover, in the present embodiment, in addition to the light-emitting layer 3 and the layers with charge injection properties and charge transport properties, the organic layer 4 includes a scattering layer 5 having light scattering properties. The organic layer 4 including the scattering layer 5 improves the light-outcoupling efficiency. In the embodiment shown in FIG. 1, the scattering layer 5 is between the light-emitting layer 3 and the light-reflective electrode 2. More specifically, according to a layer configuration of the organic layer 4 in the embodiment of FIG. 1, the hole-injection layer 11, the hole-transport layer 12, the light-emitting layer 3, a first electron-transport layer 13a, the scattering layer 5, a second electron-transport layer 13b, and the electron-injection layer 14 are arranged in this order from the transparent electrode 1. Namely, the scattering layer 5 is between the first electron-transport layer 13a and the second electron-transport layer 13b or is inside the electron-transport layer 13.

The scattering layer 5 has a property of scattering light from the light-emitting layer 3. The scattering layer 5 is obtained by dispersing scattering material in a layer, for example. In the present embodiment, in the scattering layer 5, scattering particles 8 are dispersed uniformly into a layer medium 9.

Examples of the scattering particles 8 include inorganic particles and organic particles both having scattering properties. For example, silica particles (SiO₂), ZnO (zinc oxide), V₂O₅ (vanadium pentoxide), and TiO₂ (titanium oxide) may be used for the scattering particles 8. When nanoparticles (fine particles in a nano-scale range) are used as the scattering particles 8, light scattering properties of the scattering layer 5 are further improved. The particle size of the aforementioned nanoparticles may fall within a range of 10 to 150 nm, for example. The particle size of the particles may be measured with a laser diffraction particle size distribution meter. Moreover, the layer medium 9 may be made of appropriate organic material or inorganic material. For example, the layer medium 9 may be made of material used for the hole-transport layer 12 or the electron-transport layer 13.

The scattering layer 5 in which the scattering particles 8 are dispersed into and arranged in the layer medium 9 is prepared by, for example, forming a layer of the scattering particles 8, and disposing the material for the layer medium 9 thereon in such a manner to fill a gap between the scattering particles 8 with the layer medium 9. Consequently, the scattering layer 5 is formed on the organic layer 4. In another method, the scattering layer 5 is formed on the organic layer 4 by disposing thereon a mixture of the layer medium 9 and the scattering particles 8.

In the present embodiment, a standing wave results from interference of (waves of) light emitted from the light-emitting layer 3, and a center position C of the thickness (a position at a half of the thickness) of the scattering layer 5 is at a particular position. A maximum intensity of the standing wave at the particular position is 80% or more of a peak value of an intensity of the standing wave, provided that the intensity equal to the peak value is expressed as 100%. Besides, it is not necessary that the scattering layer 5 show such high scattering properties to cause perfect diffusion. When the scattering layer 5 has such high scattering properties, the scattering layer 5 may destroy interfering light and therefore a standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent.

In a general organic electroluminescence element, light generated by combination of holes and electrons at a light-emitting source PO in the light-emitting layer 3 is divided broadly into light that propagates toward the transparent electrode 1 and light that propagates toward the light-reflective electrode 2. The light that propagates toward the transparent electrode 1 directly from the light-emitting layer 3 passes through the transparent electrode 1 and the substrate 7, and goes outside. A track of this light is shown by arrow P1 in FIG. 1. The light that propagates toward the light-reflective electrode 2 from the light-emitting layer 3 is reflected by the light-reflective electrode 2 so as to propagate toward transparent electrode 1, and subsequently passes through the transparent electrode 1 and the substrate 7, and goes outside. A track of this light is shown by arrow P2 in FIG. 1. Note that although there are many light directions that incline to a stacking direction (in the direction vertical to the surface of the substrate 7) in addition to the light direction parallel to the stacking direction, FIG. 1 shows a simplified case.

In this regard, light has the wave nature, and therefore the standing wave A results from interference between the light (indicated by arrow P1) propagating directly towards the transparent electrode 1 and the light (indicated by arrow P2) reflected by the light-reflective electrode 2. In other words, the organic electroluminescence element is formed of a multi-layered film including layers with different refractive indices, and the standing wave A is caused by interference inside the multi-layered film. The standing wave A resulting from the interference as described above is represented by a variation in the intensity of the light. FIG. 1 shows a state where the standing wave A arises as a result of the interference of light. This standing wave A has an anti-node A1 and a node A2. The standing wave A as shown in FIG. 1 has a greater intensity at the anti-node A1 and a lower intensity at the node A2. In this regard, a light energy density at the anti-node A1 of the standing wave A can be greater while a light energy density at the node A2 of the standing wave A can be lower. In the standing wave A, nodes and anti-nodes present alternately. The peak value (maximum) of the intensity is a maximum light intensity (maximum intensity) at a top of the standing wave A (i.e., at the anti-node A1). It is preferable that the maximum intensity, at each position in a predetermined region of the scattering layer 5 in the thickness direction, of the standing wave A is 80% or more of the peak value of the intensity of the standing wave A, the center of the predetermined region being at the position (the top; the anti-node A1) corresponding to the peak value of the intensity of the standing wave A.

In the present embodiment, the center position C in the thickness direction of the scattering layer 5 is in a particular region (predetermined region). Regarding the aforementioned light intensity (intensity), a maximum intensity of the standing wave at each position in the particular region is 80% or more of the peak value of the intensity of the standing wave A. In short, the center position C is nearby the anti-node A1 of the standing wave A. Scattering properties vary depending on where the scattering layer 5 is provided between the node and anti-node. When the anti-node A1 of the standing wave A is present in the scattering layer 5, the scattering properties are more improved. Since light is scattered at the position of the anti-node A1 of the standing wave A where the energy density of light is greatest, an amount of light emitted outside is increased.

Here, in order to determine a position of the scattering layer 5 as described above, it is preferable that the center position C of the scattering layer 5 is at any one of positions of 1/4λ, 3/4λ, 1/4λ*(2w+1) wherein λ represents a wavelength of the standing wave A of light and w is a positive integer. Specifically, in an example in which a refractive index of the whole organic layer 4 is designed to fall within a range of 1.70 to 1.85, the center position C of the scattering layer 5 is spaced at a predetermined distance D from a lower face (a first surface of the light-reflective electrode 2) 202 so as to be in the particular region. The maximum intensity at each position in the particular region is 80% or more, based on the peak value of the intensity of the standing wave A. In this example, the aforementioned wavelength λ of the standing wave A preferably falls within a range of 525 to 585 nm, and the predetermined distance D preferably falls within a range of 60 to 95 nm (1/4λ) or within a range of 190 to 280 nm (3/4λ). In this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable.

In the past, the configuration of the scattering layer 5 itself has been modified for the purpose of improving scattering properties. In the present embodiment, the scattering properties are more effectively improved by adjusting the position of the scattering layer 5, in addition to modifying the configuration of the scattering layer 5. Besides, the scattering properties are more effectively improved by forming the scattering layer 5 nearby the position of the anti-node A1 (nearby the position of 1/4λ or 3/4λ), that is, setting the scattering layer 5 in the particular region. The maximum intensity of the standing wave A at each position in the particular region is 80% or more of the peak value, the standing wave A being caused by interference of light generated in the light-emitting layer 3. Note that not only the center position C but also an interface 502 between the scattering layer 5 and an adjacent layer thereto (an interface close to the transparent electrode 1, that is, the second interface of the scattering layer 5), an interface 501 close to the light-reflective electrode 2 (a first interface of the scattering layer 5)), or both interfaces 501 and 502 may be provided in the particular region. The maximum intensity of the standing wave A at each position in the particular region is 80% or more of the peak value of the intensity of the standing wave A. The scattering properties are more improved as the scattering layer 5 is provided closer to the anti-node A1 of the standing wave A.

It is not necessary that the scattering layer 5 show such high scattering properties to cause perfect diffusion. When the scattering layer 5 has such high scattering properties, the scattering layer 5 may destroy interfering light, and therefore the standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent. Accordingly, it is not necessary that particles used for the scattering layer 5 have such a great particle size to cause Mie-scattering, in an optical wavelength size. The particles used for the scattering layer 5 may have such a particle size to cause Rayleigh scattering that is weaker than the Mie-scattering, that is, may be particles having the particle size of 150 nm or less, or 100 nm or less, in the optical wavelength size.

The center position C of the scattering layer 5 is preferably in a prescribed region where a distance from the position where the intensity of light is to be the peak value within 10% in the thickness direction, given that regarded as 100% is a distance in the thickness direction between a position (at a top of the standing wave A; at the anti-node A1 of the standing wave A) where the intensity of light (standing wave A) is to be the peak value and a position (at lowest point of the standing wave A; at the node A2 of the standing wave A) where the intensity is minimum. Namely, the center position C of the scattering layer 5 is preferably at a position 1/4λ or 3/4λ distant from the lower face 202 of the light-reflective electrode 2 wherein A represents the wavelength of the standing wave A. Specifically, in an example in which a refractive index of the whole organic layer 4 is designed to fall within a range of 1.70 to 1.85, provided that the wavelength λ of the standing wave A falls within a range of 525 to 585 nm, the center position C of the scattering layer 5 is spaced at a distance from the lower face 202 of the light-reflective electrode 2, the distance falling within a range of 60 nm to 95 nm or of 190 nm to 280 nm. As shown in FIG. 6, in this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable. Here, the intensity of light decreases with an increase in the distance from the position where the intensity of the light (standing wave A) is to be the peak value. However, in a case in which the distance from the position where the maximum intensity of the light is the peak value falls within the range, it is more possible that the maximum intensity of the standing wave A at each position in the prescribed region is 80% or more of the peak value. In the case, the node A2 of the standing wave A is present at the lower face 202 of the light-reflective electrode 2. It is preferable that no node A2 of the standing wave A is present at an upper face 101 of the transparent electrode 1. In this preferable case, it is possible to suppress a drop in the intensity of the light emitted through the lower face 702 of the substrate 7.

Besides, the standing wave A has the node A2 present at the surface 202 of the light-reflective electrode 2, and the center position C of the scattering layer 5 is at the anti-node A1 of the standing wave A as described above. As a result of that, it is possible to improve the scattering intensity of light and thus it is possible to improve the light-outcoupling efficiency. Namely, when the scattering layer 5 is at the anti-node of the standing wave A (in the particular region, note that the maximum intensity at each position in the particular region is 80% or more of the peak value of the intensity of the standing wave A), it is possible to scatter light effectively because the intensity of the standing wave A is in proportion to a square of the amplitude thereof. Furthermore, when the node A2 of the standing wave A is present at the position of the reflective electrode, the standing wave A can exist stably.

In the present embodiment, the scattering layer 5 is included within the organic layer 4. In the past, it has been known that the scattering layer 5 is formed between an electrode and a substrate, however, this causes a problem of increasing the cost due to addition of a step of forming the scattering layer 5 and of the cost of material for the scattering layer 5. Besides, in a case where the scattering layer 5 is formed on a surface of the substrate 7 close to the organic layer 4, the scattering layer 5 is provided on the outside of the transparent electrode 1 to be in contact with the transparent electrode 1. Therefore, when a surface of the scattering layer 5 is undulating, the transparent electrode 1 is to have an undulating surface. In such a case where the surface of the electrode is undulating, it is likely to cause short-circuit between the opposite electrodes and a problem of a drop in productivity. Furthermore, in the manufacturing process, the scattering layer 5 is exposed to air and moisture and therefore absorbs the moisture, and the remaining moisture passes through the electrode and affects the organic layer 4 adversely. Consequently, there are problems that light-emitting efficiency is decreased and lifetime is shortened.

In contrast, in the present embodiment, the scattering layer 5 is located inside the organic layer 4 and is disposed between the electrodes (between the light-reflective electrode 2 and the transparent electrode 1). Such a structure including the scattering layer 5 can be obtained by substituting, with the scattering layer 5, part of the organic layer 4 composing the organic electroluminescence element. Therefore, it is not necessary to form another scattering layer 5 outside the organic layer 4, and the scattering layer 5 can be formed of materials for composing the organic layer 4. Hence, it is possible to reduce the cost. Moreover, it is not necessary to form the scattering layer 5 on the surface 101 of the substrate 7 close to the transparent electrode 1, and therefore it is possible to suppress short-circuit between the electrodes due to unevenness of the scattering layer on the surface of the substrate. Besides, in the manufacturing process, there is no chance for the scattering layer 5 on the substrate to absorb moisture, and therefore it is possible to suppress drops in efficiency and lifetime. As described above, the organic electroluminescence element of the present embodiment has advantages not only in the light-outcoupling efficiency but also in the cost and the manufacturing process, and furthermore in reliability and stability.

The scattering layer 5 is provided between the electrodes (between the light-reflective electrode 2 and the transparent electrode 1) and is included within the organic layer 4. In the present embodiment, the scattering layer 5 is disposed between the light-reflective electrode 2 and the light-emitting layer 3, however, the scattering layer 5 may be on either one of a side close to the light-reflective electrode 2 or a side close to the transparent electrode 1 of the light-emitting layer 3. Namely, the scattering layer 5 may be provided between the light-emitting layer 3 and the light-reflective electrode 2 or between the light-emitting layer 3 and the transparent electrode 1. In brief, the scattering layer 5 may be provided at any position that is corresponding to the anti-node A1 of the standing wave A.

The scattering layer 5 preferably has a thickness smaller than the emission wavelength of light from the light-emitting layer 3. With the thickness, scattering by the scattering layer 5 can be not weak scattering rather than perfect diffusion, and therefore scattering performance can be exhibited in a state in which the node and the anti-node of the standing wave A caused by the light interference are kept to an extent. Two or more scattering layers 5 may be provided. Note that in a case where two or more light-emitting layers 3 are provided, the scattering layers 5 corresponding to the light-emitting layers 3 may be provided, respectively. Regarding the thickness of the scattering layer 5, it is preferable that smaller the thickness is, as smaller the emission wavelength is. This is because when the emission wavelength is smaller, equivalent scattering performance is exhibited with the smaller thickness. Moreover, it has been known that the intensity of Rayleigh scattering is in proportion to the number of particles, in proportion to the particle size raised to the power of six, and in inverse proportion to the wavelength raised to the power of four. Therefore, in a case the two or more scattering layers 5 are formed for the purpose of use of Rayleigh scattering, the configuration (thickness and particle size) of the scattering layer 5 is designed on the basis of the emission wavelength of each light-emitting layer, with taking into account of the number of scattering particles, the particle size of the scattering particle, and the wavelength. Here, as the thickness of the scattering layer 5 increases, it is more facilitated that the scattering layer 5 is provided at the particular position, that is, nearby the anti-node A1. The maximum intensity of the standing wave A at the particular position is 80% or more of the peak value. Therefore, possibility of exhibiting sufficient scattering performance is increased. However, when the scattering layer 5 contains inorganic material, the increase in the thickness of the scattering layer 5 may cause an increase in voltage, and as a result, may cause a problem of not obtaining the effect of improving electrical power efficiency. Therefore, too thick scattering layer 5 is not preferable. In summary, the scattering layer 5 preferably has the thickness smaller than the emission wavelength.

Specifically, the thickness of the scattering layer 5 is preferably 20 nm or more but 300 nm or less. In a case where the thickness falls within this range, it is more possible to effectively obtain the scattering effect while the excessive diffusion effect is suppressed. Furthermore, the thickness of the scattering layer 5 is preferably 30 nm or more. In a case where the two or more light-emitting layers 3 are provided, when the thickness of the scattering layer 5 is 30 nm or more, it is possible to enhance the scattering intensity regarding the more amount of light as described above.

In the embodiment shown in FIG. 1, the scattering layer 5 is provided between the light-emitting layer 3 and the light-reflective electrode 2. Specifically, the scattering layer 5 is positioned between the electron-transport layer 13 (a first electron-transport layer 13a) close to the transparent electrode 1 and the electron-transport layer 13 (a second electron-transport layer 13b) close to the light-reflective electrode 2, that is, a structure is provided where the scattering layer 5 is provided between and positioned at the middle of the two electron-transport layers 13 and 13. As described above, the scattering layer 5 is provided between the electron-transport layers 13 in a preferable embodiment. Accordingly, a difference in the refractive index occurs on the scattering layer 5 between the electron-transport layers 13, and therefore it is possible to provide a structure showing scattering performance. Besides, when the first electron-transport layer 13a and the second electron-transport layer 13b are made of the same material, the manufacturing process is made simple. Moreover, when the layer medium 9 of the scattering layer 5 is made of the same material as one of or both of the two electron-transport layers 13a and 13b, the manufacturing process is made simpler.

As shown in the embodiment shown in FIG. 1, it is preferable that the scattering layer 5 is provided between the light-emitting layer 3 and the light-reflective electrode 2 because scattering performance is enhanced. Light reflection occurs on a region between the light-emitting layer 3 and the light-reflective electrode 2, and the scattering properties are more effectively shown by intensifying the standing wave A caused by the interference between the light-emitting layer 3 and the light-reflective electrode 2 to be greater than that between the light-emitting layer 3 and the transparent electrode 1.

Each layer of the aforementioned organic electroluminescence element is made of an appropriate material.

The transparent electrode 1 is a layer that has electrical conductivity and is transparent, but is not limited to a particular one. The transparent electrode 1 may be made of metal or metal oxide. Examples of material for the transparent electrode 1 include ITO (Indium Tin Oxide) and IZO (Indium Zinc Oxide).

Examples of material for the hole-injection layer 11 include PEDOT/PSS, CuPc (Copper (II) phthalocyanine), and MoO₃ (Molybdenum (VI) Oxide). Here, PEDOT/PSS is a polymer complex in which PEDOT (poly(3,4-ethylenedioxythiophene)) and PSS (poly(styrene sulfonic acid)) coexist.

Examples of material for the hole-transport layer 12 include α-NPD and starburst amines (e.g., m-MTDATA).

Examples of material for the electron-transport layer 13 include Alq₃ and a triazole derivative (e.g., TAZ).

Examples of material for the electron-injection layer 14 include Li and Liq. FIG. 1 shows the electron-injection layer 14 as a part of the organic layer 4.

The light-emitting layer 3 may be made of an appropriate electroluminescent material. As the material for the light-emitting layer 3, either one type of a light-emitting material for red (emission wavelength: 605 to 630 nm), a light-emitting material for green (emission wavelength: 540 to 560 nm), and a light-emitting material for blue (emission wavelength: 440 to 460 nm) may be used, or two or more types may be used. In the embodiment shown in FIG. 1, for example, the light-emitting layer 3 may be either one of a green light-emitting layer, a red light-emitting layer, and a blue light-emitting layer. Besides, the light emitted from the light-emitting layer 3 may be fluorescence or phosphorescence.

Examples of the light emitting material include perylene (blue), quinacridone (green), Ir(PPy)₃ (green), and DCM (red).

The organic electroluminescence element may include two or more light-emitting layers 3. When the organic electroluminescence element includes the two or more light-emitting layer 3, color adjustment is more facilitated. For example, the organic electroluminescence element configured to emit white light may be obtained with using a combination of red light, green light, and blue light.

The light-reflective electrode 2 is a layer that has electrical conductivity and light reflectivity, and is made of metal or the like, but is not limited to a particular one. Examples of material for the light-reflective electrode 2 include aluminum, Mg, and Ag.

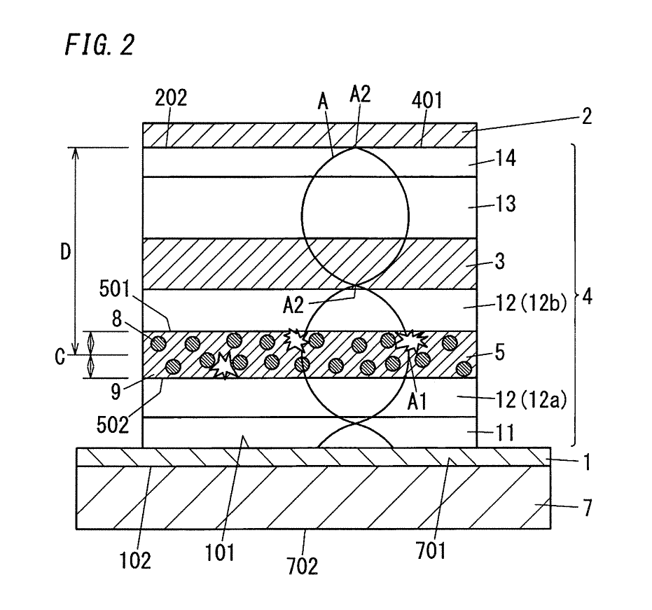

FIG. 2 shows another embodiment of the organic electroluminescence element in which the scattering layer 5 is between the light-emitting layer 3 and the transparent electrode 1. As shown in this embodiment, the scattering layer 5 may be between the light-emitting layer 3 and the transparent electrode 1. In the present embodiment, material or the like for each layer may be the same as the embodiment shown in FIG. 1.

In the organic electroluminescence element of the present embodiment, the scattering layer 5 is between the hole-transport layer 12 (a first hole-transport layer 12a) close to the transparent electrode 1 and the hole-transport layer 12 (a second hole-transport layer 12b) close to the light-reflective electrode 2, that is, a structure is provided where the scattering layer 5 is between and at the middle of the hole-transport layers 12 and 12. As described above, the scattering layer 5 is provided between the hole-transport layers 13 in a preferable embodiment. The scattering layer 5 is formed in a similar manner to that of the embodiment shown in FIG. 1. For example, the scattering layer 5 may be formed by dispersing the scattering particles 8 in the layer medium 9 uniformly. Besides, when the first hole-transport layer 12a and the second hole-transport layer 12b are made of the same material, the manufacturing process is made simple. Moreover, when the layer medium 9 of the scattering layer 5 is made of the same material as one of or both of the two first hole-transport layers 12a and 12b, the manufacturing process is made simpler.

Also in the embodiment shown in FIG. 2, it is not necessary that the scattering layer 5 show such high scattering properties to cause perfect diffusion. When the scattering layer 5 has such high scattering properties, the scattering layer 5 may destroy interfering light, and therefore a standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent. Accordingly, it is not necessary that particles used for the scattering layer 5 have such a great particle size to cause Mie-scattering, in an optical wavelength size. The particles used for the scattering layer 5 may have a particle size to cause Rayleigh scattering that is weaker than the Mie-scattering, that is, may be particles having the particle size of 150 nm or less, or 100 nm or less, in the optical wavelength size. Furthermore, the center position C is set in such a manner to be within the particular region. The maximum intensity, at each position in the particular region, of the standing wave A caused by the interference is 80% or more of the peak value of the intensity of the standing wave A. Namely, it is preferable that the center position C of the scattering layer 5 in the thickness direction is by a distance of 1/4λ or 3/4λ apart from the lower face (the first surface of the light-reflective electrode 2) 202 wherein A represents a wavelength of the standing wave A of light. Specifically in an example in which a refractive index of the whole organic layer 4 is designed to fall within a range of 1.70 to 1.85, provided that the wavelength λ of the standing wave A falls within the range of 525 to 585 nm, the center position C of the scattering layer 5 is spaced at a distance from the lower face 202 of the light-reflective electrode 2, the distance preferably falling within a range of 60 to 95 nm or within a range of 190 to 280 nm. In this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable. Specific design for each layer may be the same as in the embodiment shown in FIG. 1. Also in the present embodiment, the scattering layer is nearby a position corresponding to the anti-node of the standing wave, and therefore, it is possible to enhance a scattering intensity of intensified light, and therefore it is possible to improve the light-outcoupling efficiency. Furthermore, it is preferable that the node A2 of the standing wave A is formed at the lower face 202 of the light-reflective electrode 2 and no node A2 of the standing wave A is present at the upper face 101 of the transparent electrode 1. Accordingly, it is possible to suppress a drop in the intensity of the light emitted through the lower face 702 of the substrate 7.

Moreover, the standing wave A has the node A2 present at the surface 202 of the light-reflective electrode 2, and the center position C of the scattering layer 5 is at the anti-node A1 of the standing wave A as described above. As a result of that, it is possible to improve the scattering intensity of light and thus the light-outcoupling efficiency. Namely, when the scattering layer 5 is positioned at the anti-node of the standing wave A (in the particular region, note that the maximum intensity in the particular region is 80% or more of the peak value of the intensity of the standing wave A), it is possible to effectively scatter light because the intensity of the standing wave A is in proportion to a square of the amplitude thereof. Furthermore, when the node A2 of the standing wave A is present at the position of the reflective electrode, the standing wave A can exist stably.

As similar to the embodiment shown in FIG. 1, the light-emitting layer 3 may be made of an appropriate electroluminescent material. As the material for the light-emitting layer 3, either one type of a light-emitting material for red (emission wavelength: 605 to 630 nm), a light-emitting material for green (emission wavelength: 540 to 560 nm), and a light-emitting material for blue (emission wavelength: 440 to 460 nm) may be used, or two or more types may be used. In the embodiment shown in FIG. 2, for example, the light-emitting layer 3 may be either one of a green light-emitting layer, a red light-emitting layer, and a blue light-emitting layer. Besides, the light emitted from the light-emitting layer 3 may be fluorescence or phosphorescence.

Examples of the light emitting material include perylene (blue), quinacridone (green), Ir(PPy)₃ (green), and DCM (red).

The organic electroluminescence element may include two or more light-emitting layers 3. When the organic electroluminescence element includes the two or more light-emitting layer 3, color adjustment is more facilitated. For example, the organic electroluminescence element for emitting white light may be obtained with using a combination of red light, green light, and blue light.

It is preferable that the scattering layer 5 is provided between the light-emitting layer 3 and the transparent electrode 1 like the embodiment shown in FIG. 2 because this may suppress deterioration of the light-emitting layer 3 due to ultraviolet rays. Ultraviolet rays of natural light are scattered in the scattering layer 5, and therefore are less likely to strike the light-emitting layer 3 directly.

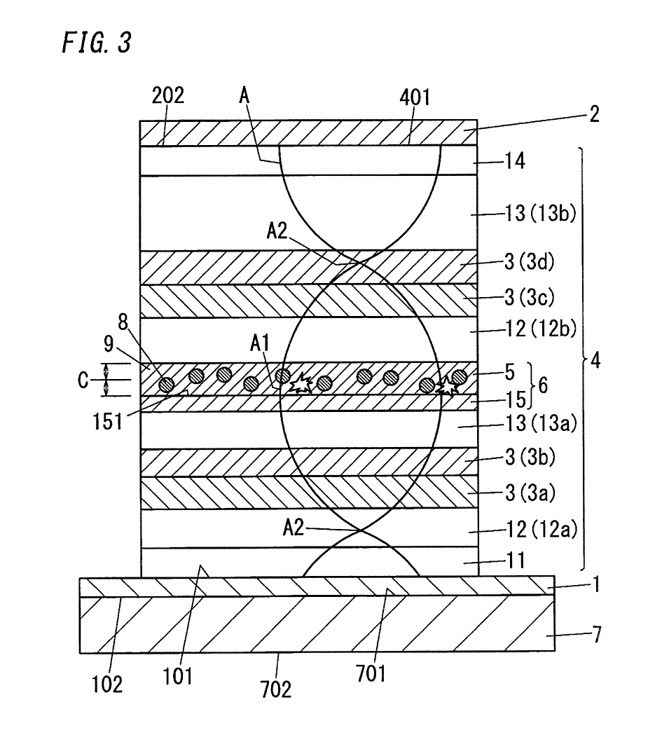

FIG. 3 shows another embodiment of the organic electroluminescence element. In the organic electroluminescence element, an organic layer 4 includes two or more light-emitting layers 3 while an interlayer 6 is between the two or more light-emitting layers 3. Namely, the organic electroluminescence element is a multi-unit type where two or more multi-units are stacked while the interlayer 6 is between the two or more multi-units.

In the present embodiment, the organic layer 4 includes four light-emitting layers 3. Two light-emitting layers 3 are included in a first light-emitting unit that is between the transparent electrode 1 and the interlayer 6 while the other two light-emitting layers 3 are included in a second light-emitting unit that is between the interlayer 6 and the light-reflective electrode 2.

The first light-emitting unit includes a hole-injection layer 11, a first hole-transport layer 12a, a first light-emitting layer 3a, a second light-emitting layer 3b, and a first electron-transport layer 13a. The second light-emitting unit includes a second hole-transport layer 12b, a third light-emitting layer 3c, a fourth light-emitting layer 3d, a second electron-transport layer 13b, and an electron-injection layer 14. The interlayer 6 is provided between the first electron-transport layer 13a the first light-emitting unit and the second hole-transport layer 12b, which compose the first light-emitting unit and the second light-emitting unit, respectively.

The four light-emitting layers 3 may include, for example, the first light-emitting layer 3a configured to emit blue light, the second light-emitting layer 3b configured to emit green light, the third light-emitting layer 3c configured to emit red light, and the fourth light-emitting layer 3d configured to emit green light, which are arranged in this order from the transparent electrode 1. As describe above, when red, green, and blue are selected as emission colors of light emitted from the light-emitting layers 3 and the whole set of light-emitting layers 3 is designed to emit a combination of light (light rays) with emission colors of red/green/blue, it is possible to obtain light with an emission color of white. Note that, each light-emitting layer 3 may emit fluorescence or phosphorescence.

In the present embodiment, it is not necessary that the scattering layer 5 show such high scattering properties to cause perfect diffusion. When the scattering layer 5 has such high scattering properties, the scattering layer 5 may destroy interfering light, and therefore a standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent. Accordingly, it is not necessary that particles used for the scattering layer 5 have such a great particle size to cause Mie-scattering, in an optical wavelength size. The particles used for the scattering layer 5 may have such a particle size to cause Rayleigh scattering that is weaker than the Mie-scattering, that is, may have the particle size of 150 nm or less, or 100 nm or less, in the optical wavelength size. Moreover, the scattering layer 5 is preferably included in the interlayer 6. When the scattering layer 5 is included in the interlayer 6, it is possible to effectively improve the light-outcoupling efficiency. In this regard, when the two or more light-emitting layers 3 are provided, the scattering layer 5 may be provided between the transparent electrode 1 and the first light-emitting layer 3a (i.e., the light-emitting layer 3 closest to the transparent electrode 1) or between the light-reflective electrode 2 and the fourth light-emitting layer 3d (i.e., the light-emitting layer 3 closest to the light-reflective electrode 2). Besides, the scattering layer 5 may be provided between the second light-emitting layer 3b and the third light-emitting layer 3c (between the light-emitting layers 3 and 3). However, it is possible to improve light-outcoupling efficiency more effectively by that the interlayer 6 includes the scattering layer 5.

In the present embodiment, the interlayer 6 includes the scattering layer 5 and a charge-generation layer 15. As described above, the interlayer 6 may include a layer (e.g., the charge-generation layer 15) in addition to the scattering layer 5 arbitrarily, or only the scattering layer 5 may serve as the interlayer 6. Namely, in the multi-unit type organic electroluminescence element, the interlayer 6 functions to transfer electrons toward the anode (transparent electrode 1) and to transfer holes toward the cathode (light-reflective electrode 2). The scattering layer 5 may be formed in the same manner as that of the embodiment shown in FIG. 1. For example, the scattering layer 5 is formed by dispersing the scattering particles 8 in the layer medium 9 uniformly. In a case where the scattering layer 5 serves as the interlayer 6 per se, one layer serves as both of the scattering layer 5 and the interlayer 6, and therefore the effect of reducing the cost may be obtained due to reducing the material cost. Moreover, even in a case where the interlayer 6 includes a layer in addition to the scattering layer 5, for example, formation of the interlayer 6 can be facilitated by that the interlayer 6 has a structure where the scattering layer 5 is present between the two charge-generation layers 15 made of the same material while the scattering layer 5 is composed of the layer medium 9 and the scattering particles 8 uniformly dispersed therein, the layer medium 9 being made of the material for charge-generation layer 15. In this regard, when oxide (e.g., VₙO₅ wherein n is a positive integer) that shows the charge generation effect is used as the scattering particles included in the interlayer 6, a layer can show both effects of scattering and charge generation and is useful.

As shown in FIG. 3, the interlayer 6 may have a stacked structure of the charge-generation layer 15 and the scattering layer 5. In this regard, the charge-generation layer 15 preferably has a stacked structure of an n-type charge-transport layer and a p-type charge-transport layer. Accordingly, generation and transport of the charges in the interlayer 6 are improved. Such an interlayer 6 is prepared by forming a layer of scattering particles on the charge-generation layer 15. A preferred example for material for the n-type charge-transport layer is a metal-doped layer, for example, Cs-doped 2,9-dimethyl-4,7-diphenyl-1,10-phenanthroline. A preferred example for material for the p-type charge-transport layer is metal oxide, for example, V₂O₅, WO₃, and MoO₃. When metal oxide particles are used, the particles can also serve as scattering particles, and in this case, the p-type charge-transport layer may serve as parts of the scattering layer 5 or as a layer to assist in scattering by the scattering layer 5. Note that it is preferable that the n-type charge-transport layer is provided close to the anode (transparent electrode 1) and the p-type charge-transport layer is provided close to the cathode (light-reflective electrode 2).

Besides, the interlayer 6 may have a configuration in which the charge-generation layer 15 has a stacked structure of the n-type charge-transport layer and the p-type charge-transport layer and the whole scattering layer 5 consists of the p-type charge-transport layer. Such an interlayer 6 can be prepared by forming a p-type charge-transport layer of material that shows both scattering and charge generation effects. For example, when oxide (e.g., VₙO₅ wherein n is a positive integer) that shows the charge generation effect is used as the scattering particles, a layer that shows both scattering and charge generation effects can be formed.

Material for the charge-generation layer 15 for composing the interlayer 6 and material for the layer medium 9 are not limited, but the aforementioned VₙO₅ (wherein n is a positive integer) or the like may be used as the material. Note that the scattering layer 5 or a part of the interlayer 6 is composed of a layer of particles, gaps between the particles may be filled with material applied thereon. In this case, the material for filling the gaps between the particles serves as the layer medium 9.

Also in the embodiment shown in FIG. 3, the center position C is determined in such a manner to be in the particular region. The maximum intensity, at each position in the particular region, of the standing wave A caused by the interference is 80% or more of the peak value of the intensity of the standing wave A. Specific design may be the same as that of the embodiments shown in FIGS. 1 and 2. However, in the present embodiment, the center position C is spaced by 1/2λ from the lower face (the first surface of the light-reflective electrode 2) 202 wherein λ represents the wavelength of the standing wave A. Accordingly, in the present embodiment, a configuration is provided in which the standing wave A is less likely to have nodes A2 at both ends thereof in the organic layer 4. Besides, it is not necessary that regarding all the two or more light-emitting layers 3, two or more scattering layers 5 corresponding to the light from the light-emitting layers 3 are formed in such a manner that each center position C of scattering layer 5 is in the particular region. The maximum intensity, at each position of the particular region, of light (standing wave) caused by the interference is 80% or more of the peak value of the intensity of the standing wave A. It is sufficient that at least one scattering layer 5 satisfies the aforementioned relation. However, it is preferable that as many light-emitting layers 3 as possible satisfy the relation, and that two or more, three or more, or all the light-emitting layers 3 satisfy the relation. Also in the embodiment shown in FIG. 3, the scattering layer 5 is positioned nearby a position corresponding to the anti-node of the standing wave arising as a result of the interference, and therefore it is possible to increase a scattering intensity of intensified light, and therefore to enhance the light-outcoupling efficiency.

When the two or more light-emitting layers 3 are provided, and when a green light-emitting layer is provided, the scattering layer 5 is preferably formed in such a manner that the center position C is within the particular region. The maximum intensity of the standing wave at each position in the particular region is 80% or more of the peak value of the intensity of the standing wave A, regarding the light with the wavelength emitted from the green light-emitting layer. The wavelength of green light falls within the range between wavelengths of blue light and red light, and therefore when the position of the scattering layer 5 is determined with reference to the green light, it is facilitated to increase the intensity of light including blue light and red light by the scattering. Moreover, by determining the position with a reference to the green light, it is more possible to position the scattering layer 5 within a particular region for either one or both of blue light and green light. The maximum intensity, at each position in this particular region for either one or both of blue light and green light, of the standing wave A caused by the interference is 80% or more of the peak value of the intensity of the standing wave A, regarding either one or both of blue light and red light. Besides, since green light affects greatly on visible light sensitivity of a human compared with other color light, it is possible to increase the intensity of light more effectively with intensifying green light than with intensifying other color light.

In a case where the light-emitting layers 3 are provided, the positions of the node and the anti-node of the standing wave caused by the interference of light vary in accordance with the wavelength. In this regard, the positions of the anti-nodes of the standing waves of red light and blue light are likely to be within a region where a distance from the anti-node of the green light falls within a range of 10 to 15 nm. In other words, the emission wavelength of the green light is between the wavelengths of the blue light and the red light, and therefore distances between the anti-nodes A1 of the standing waves A of blue light, green light, and red light fall within the range of about 30 nm. Hence, when the middle position in the thickness of the scattering layer 5 is at the anti-node A1 of the standing wave A of the green light while the thickness of the scattering layer 5 is 30 nm or more, it is more possible to allow the anti-nodes A1 of the standing waves A of the red light, the green light, and the blue light to be present inside the scattering layer 5. Accordingly, it is possible to cause scattering effect on more kinds of light, enhance the scattering intensity of intensified light, and improve light-outcoupling efficiency.

For example, in the embodiment shown in FIG. 3 and in a case where the first light-emitting layer 3a is configured to emit blue light, the second light-emitting layer 3b is configured to emit green light, the third light-emitting layer 3c is configured to emit red light, and the fourth light-emitting layer 3d is configured to emit green light, the following design may be adopted. First, a standing wave arises as a result of interference of light (light rays) emitted from the fourth light-emitting layer 3d that is configured to emit green light, is positioned close to the light-reflective electrode 2, and provides higher contribution. The scattering layer 5 is positioned within a particular region for this standing wave. The maximum intensity of this standing wave at each position in the particular region for this standing wave is 80% or more of the peak value of the intensity of the standing wave. In this regard, when a distance between the anti-node of the standing wave of light from the fourth light-emitting layer 3d and the anti-node of the standing wave of light from the third light-emitting layer 3c is smaller than the thickness of the scattering layer 5, the scattering layer 5 is likely to be positioned within a particular region for the third light-emitting layer 3c. The maximum intensity, at each position in the particular region for the third light-emitting layer 3c, of the standing wave of light from the third light-emitting layer 3c is 80% or more of the peak value. Even when the interlayer 5 is set at a position where the intensity of the standing wave caused by interference is constantly less than 80% of the peak value thereof, the scattering layer 5 is more likely to be at a position (closer to the anti-node than to the node) where a relatively high intensity can be obtained. More preferably, a standing wave arises as a result of interference of light (light rays) emitted from the second light-emitting layer 3b configured to emit green light, and the scattering layer 5 is positioned within a particular region for this standing wave. In the particular region for this standing wave, the maximum intensity of this standing wave at each position in the particular region is 80% or more of the peak value. In this regard, the thickness of each layer (e.g., the scattering layer 5) is determined and the position of the scattering layer 5 is adjusted as possible in such a manner that, the scattering layer 5 is at a particular position for both two green lights. Each of the maximum intensities of the standing waves of both two green lights at the particular position for both two green lights is 80% or more of the peak value thereof. When a distance between the anti-node of the standing wave of light from the first light-emitting layer 3a and the anti-node of the standing wave of light from the second light-emitting layer 3b is smaller than the thickness of the scattering layer 5, the scattering layer 5 is likely to be positioned within a particular region for the first light-emitting layer 3a. The maximum intensity, at each position in the particular region for the first light-emitting layer 3a, of the standing wave of the light from the first light-emitting layer 3a is 80% or more of the peak value. Even when the interlayer 5 is at a position where the intensity of the standing wave caused by interference is constantly less than 80% of the peak value thereof, the scattering layer 5 is likely to be at a position (closer to the anti-node than to the node) where a relatively high intensity can be obtained. Accordingly, when the scattering layer 5 is positioned in such a manner that more constructive is interference of the green light emitted from light-emitting layer 3 positioned close to the light-reflective electrode 2 while more constructive is interference of the green light emitted from light-emitting layer 3 close to the transparent electrode 1, it is possible to obtain the organic electroluminescence element with high light-outcoupling efficiency.

Also, for example, in the embodiment shown in FIG. 3, a combination of fluorescence and phosphorescence may be used. As an example, the first light-emitting unit emits fluorescence and the second light-emitting unit emits phosphorescence. In such a case, it is also preferable that the scattering layer 5 is within a particular region for fluorescence. The maximum intensity, at each position in the particular region for fluorescence, of the standing wave caused by the interference of the fluorescence is 80% or more of the peak value. The scattering effect on fluorescence is achieved, and therefore the intensity of the entire light can be enhanced more effectively. Also in this case, when green fluorescence is present, it is preferable that the design be determined with reference to the green fluorescence.

In the embodiment as shown in FIG. 3, the number of the light-emitting units is two, but is not limited to this. Three or more light-emitting units may be interconnected through at least one interlayer 6. The light-emitting efficiency is multiplied by the number of the light-emitting units. Even when the current is not changed, the light-emitting efficiency increases with an increase in the number of light-emitting units. Hence, it is preferable to increase the number of the light-emitting units. In this case, the scattering layer 5 is preferably included in the interlayer 6, and when two or more interlayers 6 are provided, the scattering layer 5 may be included in at least one of the interlayers 6 or each of all the interlayers 6. The structure in which the scattering layers 5 are provided in the two or more interlayers 6 facilitates positioning the scattering layer 5 at the anti-node of the standing wave. Therefore it is possible to easily obtain the effect of improving light-emitting efficiency.

Besides, the multi-unit structure enables an increase in the total thickness of the organic layer 4 composing the organic electroluminescence element. When the total thickness of the organic layer 4 is increased, prevented is a short circuit between the opposite electrodes caused by micro-unevenness of the substrate and extraneous substance, and a defect due to leak current is prevented. Therefore, it is more possible to obtain improved efficiency of productivity in manufacturing the organic electroluminescence element.

Note that design for disposition of the scattering layer 5 in the above case where the two or more light-emitting layers 3 are provided is not limited to that including the multi-unit structure. For example, in the embodiments shown in FIGS. 1 and 2 modified to include the two or more light-emitting layers 3, when green light is used as the reference as described above, it is possible to more efficiently enhance the scattering effect.

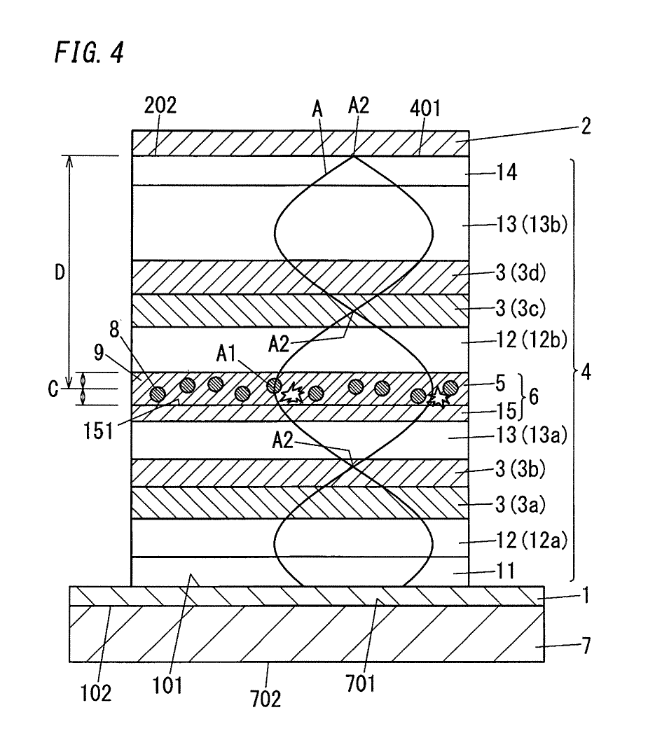

FIG. 4 shows another embodiment of the organic electroluminescence element. In the organic electroluminescence element, the organic layer 4 includes two or more light-emitting layers 3 while an interlayer 6 is between the two or more light-emitting layers 3. Namely, the organic electroluminescence element is a multi-unit type where two or more multi-units are stacked while the interlayer 6 is between the two or more light-emitting layers 3.

In the present embodiment, the organic layer 4 includes four light-emitting layers 3. Two light-emitting layers 3 are included in a first light-emitting unit disposed between the transparent electrode 1 and the interlayer 6 while the other two light-emitting layers 3 are included in a second light-emitting unit disposed between the interlayer 6 and the light-reflective electrode 2.

The first light-emitting unit includes a hole-injection layer 11, a first hole-transport layer 12a, a first light-emitting layer 3a, a second light-emitting layer 3b, and a first electron-transport layer 13a. The second light-emitting unit includes a second hole-transport layer 12b, a third light-emitting layer 3c, a fourth light-emitting layer 3d, and a second electron-transport layer 13b, and an electron-injection layer 14. The interlayer 6 is provided between the first electron-transport layer 13a and the second hole-transport layer 12b, which compose the first light-emitting unit and the second light-emitting unit, respectively.

The four light-emitting layers 3 may include, for example, the first light-emitting layer 3a configured to emit blue light, the second light-emitting layer 3b configured to emit green light, the third light-emitting layer 3c configured to emit red light, and the fourth light-emitting layer 3d configured to emit green light, which are arranged in this order from the transparent electrode 1. As describe above, when red, green, and blue are selected as emission colors of light emitted from the light-emitting layers 3, respectively, and the whole set of light-emitting layers 3 is designed to emit a combination of light (light rays) with emission colors of red/green/blue, it is possible to obtain light with an emission color of white. Note that, each light-emitting layer 3 may emit fluorescence or phosphorescence.

In this embodiment, it is not necessary that the scattering layer 5 show such high scattering properties to cause perfect diffusion. When the scattering layer 5 has such high scattering properties, the scattering layer 5 may destroy interfering light, and therefore a standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent. Accordingly, it is not necessary that particles used for the scattering layer 5 have such a great particle size to cause Mie-scattering, in an optical wavelength size. The particles used for the scattering layer 5 may have such a particle size to cause Rayleigh scattering that is weaker than the Mie-scattering, that is, may have the particle size of 150 nm or less, or 100 nm or less, in the optical wavelength size. Moreover, the scattering layer 5 is preferably included in the interlayer 6. Furthermore, it is preferable that the node of the standing wave is formed to be at the lower face 202 of the light-reflective electrode 2 and no node of the standing wave is at the upper face 101 of the transparent electrode 1. In this preferable case, it is possible to suppress a drop in the intensity of the light emitted through the lower face 702 of the substrate 7. In this regard, when the two or more light-emitting layers 3 are provided, the scattering layer 5 may be provided between the transparent electrode 1 and the first light-emitting layer 3a (i.e., the light-emitting layer 3 closest to the transparent electrode 1) or between the light-reflective electrode 2 and the fourth light-emitting layer 3d (i.e., the light-emitting layer 3 closest to the light-reflective electrode 2). Besides, the scattering layer 5 may be provided between the second light-emitting layer 3b and the third light-emitting layer 3c (between the light-emitting layers 3 and 3). However, it is possible to improve light-outcoupling efficiency more effectively by that the interlayer 6 includes the scattering layer 5.

In the present embodiment, the interlayer 6 includes the scattering layer 5 and a charge-generation layer 15. As described above, the interlayer 6 may include a layer (e.g., the charge-generation layer 15) in addition to the scattering layer 5 arbitrarily, or only the scattering layer 5 may serve as the interlayer 6. Namely, in the multi-unit type organic electroluminescence element, the interlayers 6 is preferably configured to function to transfer electrons toward the anode (transparent electrode 1) and to transfer holes transfer toward the cathode (light-reflective electrode 2). The scattering layer 5 is formed in the same manner as that of the embodiment shown in FIG. 1. For example, the scattering layer 5 is formed by dispersing the scattering particles 8 in the layer medium 9 uniformly. In a case where the scattering layer 5 serves as the interlayer 6 per se, one layer serves as both of the scattering layer 5 and the interlayer 6, and therefore the effect of reducing the cost may be obtained due to reducing the material cost. Moreover, even in a case where the interlayer 6 includes a layer in addition to the scattering layer 5, for example, formation of the interlayer 6 can be facilitated by that the interlayer 6 has a structure where the scattering layer 5 is present between the two charge-generation layers 15 made of the same material while the scattering layer 5 is composed of the layer medium 9 made of the material for charge-generation layer 15 and the scattering particles 8 uniformly dispersed therein. In this regard, when oxide (e.g., VₙO₅ wherein n is a positive integer) that shows the effect of charge generation is used as the scattering particles contained in the interlayer 6, the layer can show both scattering and charge generation and thereby is useful.

As shown in FIG. 4, the interlayer 6 may have a stacked structure of the charge-generation layer 15 and the scattering layer 5. In this regard, the charge-generation layer 15 has preferably a stacked structure of an n-type charge-transport layer and a p-type charge-transport layer. Accordingly, charge generation and charge transport in the interlayer 6 are improved. Such an interlayer 6 is prepared by forming the scattering layer 5 on an upper face 151 of the charge-generation layer 15. A preferred example for material for the n-type charge-transport layer is a metal-doped layer, for example, Cs-doped 2,9-dimethyl-4,7-diphenyl-1,10-phenanthroline. A preferred example for material for the p-type charge-transport layer is metal oxide, for example, V₂O₅, WO₃, and MoO₃. When metal oxide particles are used, the particles can also serve as scattering particles, and in this case, the p-type charge-transport layer may serve as parts of the scattering layer 5 or as a layer to assist in scattering by the scattering layer 5. Note that it is preferable that the n-type charge-transport layer is provided close to the anode (transparent electrode 1) and the p-type charge-transport layer is provided close to the cathode (light-reflective electrode 2).

Besides, the interlayer 6 may have a configuration in which the charge-generation layer 15 has a stacked structure of the n-type charge-transport layer and the p-type charge-transport layer and the whole scattering layer 5 consists of the p-type charge-transport layer. Such an interlayer 6 can be prepared by forming a p-type charge-transport layer of material that shows both scattering and charge generation effects. For example, when oxide (e.g., VₙO₅ wherein n is a positive integer) that shows the effect of charge generation is used as the scattering particles, a layer that shows both scattering and charge generation effects can be used.

Material for the charge-generation layer 15 for composing the interlayer 6 and material for the layer medium 9 are not limited, but the aforementioned VₙO₅ (wherein n is a positive integer) or the like may be used as the material. Note that the scattering layer 5 or a part of the interlayer 6 is composed of a layer of particles, gaps between the particles may be filled with material to be applied thereon. In this case, the material for filling the gaps between the particles serves as the layer medium 9.

Also in the embodiment shown in FIG. 4, the center position C is determined in such a manner to be within the particular region. The maximum intensity, at each position in the particular region, of the standing wave A caused by the interference is 80% or more of the peak value. Specific design may be the same as the embodiments shown in FIGS. 1 and 2. Namely, the center position C is preferably at a position by a distance of 1/4λ or 3/4λ apart from the lower face 202 (the first surface of the light-reflective electrode 2) of the light-reflective electrode 2 wherein λ represents the wavelength of the standing wave A. Specifically in an example in which a refractive index of the whole organic layer 4 is designed to fall within a range of 1.70 to 1.85, provided that the wavelength λ of the standing wave A falls within the range of 525 to 585 nm, the center position C of the scattering layer 5 is spaced at a distance from the lower face 202 of the light-reflective electrode 2, the distance preferably falling within a range of 60 to 95 nm or within a range of 190 to 280 nm. As shown in FIG. 6, in this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable. Besides, it is not necessary that regarding all the two or more light-emitting layers 3, two or more scattering layers 5 corresponding to the light rays from the light-emitting layers 3 are formed in such a manner that each center position C of scattering layer 5 is in the particular region. The maximum intensity, at each position in the particular region, of the standing wave A is 80% or more of the peak value. It is sufficient that at least one scattering layer 5 satisfies the aforementioned relation. However, it is preferable that as many light-emitting layers 3 as possible satisfy the relation, and that two or more, three or more, or all the light-emitting layers 3 satisfy the relation. Also in the embodiment shown in FIG. 4, the scattering layer 5 is positioned nearby the anti-node of the standing wave arising as a result of the interference, and therefore it is possible to enhance a scattering intensity of intensified light, and therefore to improve the light-outcoupling efficiency.

When the two or more light-emitting layers 3 are provided, the organic layer 4 preferably includes at least green light-emitting layer. The scattering layer 5 is preferably formed in such a manner that the center position C is set within a particular region for the green light-emitting layer. The maximum intensity, at each position in the particular region for the green light-emitting layer, of the standing wave of light with the wavelength emitted from the green light-emitting layer is 80% or more of the peak value of intensity of the standing wave. Namely, the center position C is preferably set at the position 1/4λ or 3/4λ distant from the lower face 202 of the light-reflective electrode 2 wherein A represents the wavelength of the standing wave A. Specifically in an example in which a refractive index of the whole organic layer 4 is designed to fall within a range of 1.70 to 1.85, provided that the wavelength λ of the standing wave A falls within the range of 525 to 585 nm, the center position C of the scattering layer 5 is spaced at a distance from the lower face 202 of the light-reflective electrode 2, the distance preferably falling within a range of 60 to 95 nm or within a range of 190 to 280 nm. In this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable. The wavelength of green light falls within the range between the wavelengths of blue light and red light. Therefore, when the position of the scattering layer 5 is determined with reference to the green light, it is facilitated to increase the intensities of blue light and red light by the scattering. In other words, it is preferable that as the references, selected are the above aspects that the green light emitted from the green light-emitting layer and passing through the scattering layer 5 is formed into the standing wave A due to the interference and that this standing wave A has the node A2 at the lower face 202 of the light-reflective electrode 2 and no node A2 at the upper face 101 at least at the transparent electrode 1. Accordingly, arrangement of the above scattering layer 5 can be facilitated.

Besides, the standing wave A has the node A2 present at the surface 202 of the light-reflective electrode 2, and the center position C of the scattering layer 5 is at the anti-node A1 of the standing wave A as described above. As a result of that, it is possible to improve the scattering intensity of light and thus the light-outcoupling efficiency. Namely, when the scattering layer 5 is at the anti-node of the standing wave A (in the particular region, note that the maximum intensity at each position in the particular region is 80% or more of the peak value), it is possible to effectively scatter light because the intensity of the standing wave A is in proportion to a square of the amplitude thereof. Furthermore, when the node A2 of the standing wave A is present at the position of the reflective electrode, the standing wave A can exist stably.

In the case where either one or both of blue light and red light is used in addition to the green light, the scattering layer 5 may be positioned within the region defined with reference to green light as described above. Moreover, since green light affects greatly on visible light sensitivity of a human compared with other color light, it is possible to increase the intensity of light more effectively by intensifying green light than with intensifying other color light.

Furthermore, when the two or more light-emitting layers 3 are provided, light rays of different emission colors have different wavelengths. In this regard, the anti-nodes A1 of the standing waves A, which are caused by the interference, of red light and blue light are likely to be positioned within a region where a distance from the anti-node of the green light falls within a range of 10 to 15 nm. Light rays with emission colors of blue, green, and red are formed into the standing waves A, respectively. However, the emission wavelength of green light falls between wavelengths of blue light and red light, and therefore distances between the anti-node A1 of the standing wave A of blue light and the anti-node A1 of the standing wave A of green light, between the anti-node A1 of the standing wave A of red light and the anti-node A1 of the standing wave A of green light fall within the range of about 30 nm. Hence, when the center position C of the scattering layer 5 is at the anti-node A1 of the standing wave A of the green light and the thickness of the scattering layer 5 is 30 nm or more, it is more possible to allow the anti-nodes A1 of the standing waves A of red light, green light, and blue light to be present inside the scattering layer 5. Accordingly, it is possible to obtain scattering effect on more kinds of light, enhance the scattering intensity of light intensified by the scattering layer 5, and improve light-outcoupling efficiency.

For example, in the embodiment shown in FIG. 4, in a case where the first light-emitting layer 3a is configured to emit blue light, the second light-emitting layer 3b is configured to emit green light, the third light-emitting layer 3c is configured to emit red light, and the fourth light-emitting layer 3d is configured to emit green light, the following design may be adopted. First, a standing wave arises as a result of interference of light (light rays) emitted from the fourth light-emitting layer 3d that is configured to emit green light, is positioned close to the light-reflective electrode 2, and provides higher contribution. Namely, the center position C of the scattering layer 5 is preferably at a position by a distance of 1/4λ or 3/4λ apart from the lower face 202 of the light-reflective electrode 2 wherein λ represents the wavelength of the standing wave A of the green light. Specifically in an example in which a refractive index of the whole organic layer 4 is designed to fall within a range of 1.70 to 1.85, provided that the wavelength λ of the standing wave A falls within the range of 525 to 585 nm, the center position C of the scattering layer 5 is spaced at a distance from the lower face 202 of the light-reflective electrode 2, the distance preferably falling within a range of 60 to 95 nm or within a range of 190 to 280 nm. In this case, when the wavelength λ falls within a range of 525 to 585 nm, a spectral sensitivity regarding light emitted via a lower face (a second surface of the substrate 7) 702 is 80% or more, provided that the spectral sensitivity regarding such light at a wavelength of 555 nm is 100%. Therefore, this case is preferable. Besides, when a distance between the anti-node of the standing wave of light from the fourth light-emitting layer 3d and the anti-node of the standing wave light from the light-emitting layer 3c is smaller than the thickness of the scattering layer 5, the scattering layer 5 is likely to be within a particular region for the third light-emitting layer 3c, The maximum intensity, at each position in the particular region for the third light-emitting layer 3c, of the standing wave of light from the third light-emitting layer 3c is 80% or more of the peak value. Even when the interlayer 5 is at a position where the intensity of the standing wave due to interference is constantly less than 80% of the peak value thereof, the scattering layer 5 is more likely to be at a position (closer to the anti-node than to the node) where a relatively high intensity can be obtained. More preferably, light emitted from the second light-emitting layer 3b to emit green light is formed into a standing wave due to interference, and the scattering layer 5 is positioned within the particular region. The maximum intensity of the standing wave at each position in the particular region is 80% or more of the peak value. In this regard, the thickness of each layer contained in the organic layer 4 in addition to the thickness of the scattering layer 5 is determined and the position of the scattering layer 5 is adjusted in such a manner that both of the standing waves of the two green light rays are present as standing waves caused by interferences of light emitted from the light-emitting layers 3 individually, and the scattering layer 5 is positioned as possible at the particular position. The maximum intensities of the standing waves at the position are 80% or more of the peak values of the intensities of the standing wave A. When a distance between the anti-node of the standing wave of light from the first light-emitting layer 3a and the anti-node of the standing wave of light from the second light-emitting layer 3b is shorter than the thickness of the scattering layer 5, the scattering layer 5 is more likely to be positioned within the particular region. The maximum intensities of the standing waves at each position in the particular region are 80% or more of a corresponding one of the peak values. Even when the scattering layer 5 is at a position where the intensity of the standing wave caused by interference is constantly less than 80% of the peak value thereof, the scattering layer 5 is more likely to be set at a position (closer to the anti-node than to the node) where a relatively high intensity can be obtained. Accordingly, when the scattering layer 5 is positioned in such a manner that increased are the intensities of the standing wave caused by interference of green light from the light-emitting layer 3 close to the light-reflective electrode 2 and the standing wave caused by interference of green light from the light-emitting layer 3 close to the transparent electrode 1, it is possible to obtain the organic electroluminescence element with high light-outcoupling efficiency.

Besides, for example, in the embodiment in FIG. 4, a combination of fluorescence and phosphorescence may be used. As an example, the first light-emitting unit emits fluorescence and the second light-emitting unit emits phosphorescence. In such a case, it is also preferable that the scattering layer 5 is within a particular region for fluorescence. The maximum intensity, at each position in the particular region for fluorescence, of the standing wave caused by the interference of the fluorescence is 80% or more of the peak value. The scattering effect on fluorescence is achieved, and therefore the intensity of the entire light can be enhanced more effectively. Also in this case, when green fluorescence is present, it is preferable that the design be determined with reference to the green fluorescence.

In the embodiment as shown in FIG. 4, the number of light-emitting units is two, but is not limited to this. Three or more light-emitting units may be interconnected through at least one interlayer 6. The light-emitting efficiency is multiplied by the number of the light-emitting units. Even when the current is not changed, the light-emitting efficiency increases with an increase in the number of light-emitting units. Hence, it is preferable to increase the number of the light-emitting units. In this case, the scattering layer 5 is preferably included in the interlayer 6, and when two or more interlayers 6 are provided, the scattering layer 5 may be included in at least one of the interlayers 6 or each of all of the interlayers 6. When the scattering layers 5 are provided to the two or more interlayers 6, the standing wave is caused by interference of light emitted from each light-emitting unit. In this regard, the scattering layer 5 is positioned at at least one of positions corresponding to 1/4λₓ, 3/4λₓ, 1/4λₓ(2Y+1) wherein: λₓ represents a wavelength of each standing wave; and x is a positive integer; and Y is a positive integer. Namely, due to providing the scattering layers 5 positioned corresponding to light from light-emitting units, the positions of the scattering layers 5 are identical to the anti-nodes of the standing waves, respectively. Therefore, the organic electroluminescence element is more likely to have an improved light emitting efficiency in total.

Besides, the multi-unit structure enables an increase in the total thickness of the organic layer 4 composing the organic electroluminescence element. When the total thickness of the organic layer 4 is increased, a short-circuit caused by micro-unevenness of the substrate and extraneous substance is prevented and a defect due to leak current is prevented. Therefore, it is more possible to obtain improved efficiency of productivity in manufacturing the organic electroluminescence element.

Note that design for disposition of the scattering layer 5 in the above case where the two or more light-emitting layers 3 are provided is not limited to that including the multi-unit structure. For example, in the embodiments shown in FIGS. 1 and 2 modified to include the two or more light-emitting layers 3, when green light is used as the reference as described above, it is possible to more efficiently enhance the scattering effect.

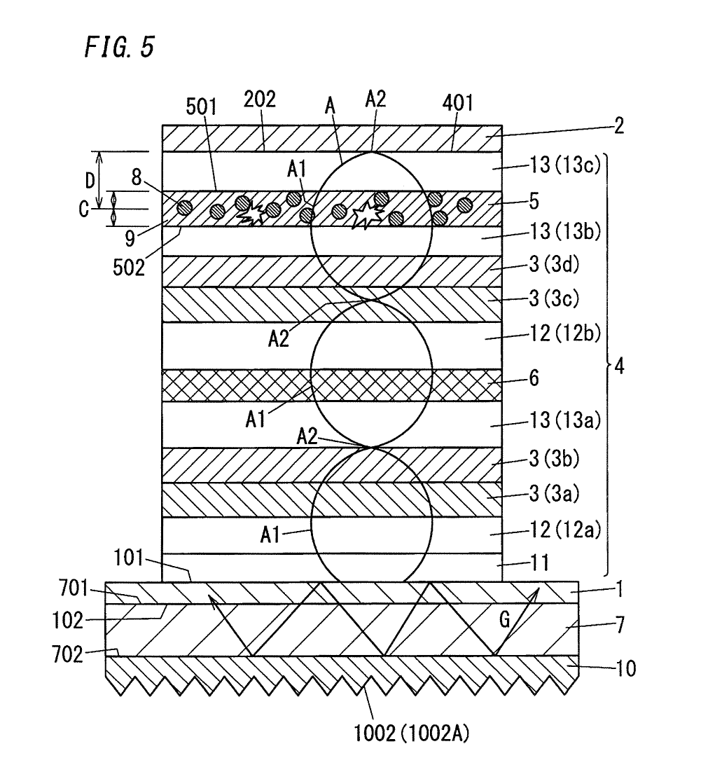

The organic electroluminescence element can be modified appropriately so long as the organic electroluminescence element does not fail to provide the aforementioned scattering effect. For example, FIG. 5 shows an embodiment of the multi-unit organic electroluminescence element in which light-outcoupling layer 10 is on an opposite side (an outside: the second surface 702 of the substrate 7) of the substrate 7 from the transparent electrode 1. In this embodiment, it is not necessary that the scattering layer 5 show such high scattering properties to cause perfect diffusion. When the scattering layer 5 has such high scattering properties, the scattering layer 5 may destroy interfering light, and therefore a standing wave A may not be formed. In contrast, when the scattering layer 5 has too poor scattering properties, there is possibility that sufficient light-outcoupling efficiency is not provided. Therefore, it is preferable that the scattering layer 5 has scattering properties while a node and an anti-node of the standing wave A caused by interference of light are maintained to some extent. Accordingly, it is not necessary that particles used for the scattering layer 5 have such a great particle size to cause Mie-scattering, in an optical wavelength size. The particles used for the scattering layer 5 may have such a particle size to cause Rayleigh scattering that is weaker than the Mie-scattering, that is, may have the particle size of 150 nm or less, or 100 nm or less, in the optical wavelength size. Besides, the scattering layer 5 is at a position corresponding to a quarter of the wavelength of the standing wave, and therefore the node A2 of the standing wave A is at the lower face (the first surface of the light-reflective electrode 2) 202.

Besides, the standing wave A has the node A2 present at the surface 202 of the light-reflective electrode 2, and the center position C of the scattering layer 5 is at the anti-node A1 of the standing wave A as described above. As a result of that, it is possible to improve the scattering intensity of light and thus the light-outcoupling efficiency. Namely, when the scattering layer 5 is positioned at the anti-node of the standing wave A (in the particular region, note that the maximum intensity of the standing wave A at each position in the particular region is 80% or more of the peak value), it is possible to scatter light effectively because the intensity of the standing wave A is in proportion to a square of the amplitude thereof. Furthermore, when the node A2 of the standing wave A is present at the position of the reflective electrode, the standing wave A can exist stably. The light-outcoupling layer 10 may be provided by disposing light-outcoupling film having a surface 1002 with an undulating structure, on the lower face 702 of the substrate 7 in such a manner that an undulating face 1002A oriented outward. Due to forming the light-outcoupling layer 10 as described above, a guided optical wave G can be extracted outside, and it is facilitated to extract light that is intensified by the scattering layer 5 to the outside. Note that in the embodiment shown in FIG. 5, although the scattering layer 5 is provided between the second electron-transport layer 13b and the third electron-transport layer 13c that are disposed between the light-reflective electrode 2 and the fourth light-emitting layer 3d, the scattering layer 5 may obviously be included in the interlayer 6.

The organic electroluminescence element configured as described above is available for various applications, for example, particularly useful for a light emitting device such as an illumination panel.

### EXAMPLES

### Example 1

On a glass substrate (substrate 7) on which an ITO film had been formed as an anode (transparent electrode 1), a hole-injection layer 11 was formed by applying PEDOT/PSS thereon and making it dry. Subsequently, a hole-transport layer 12 of α-NPD was formed thereon by vapor deposition. Next, a light-emitting layer 3 configured to emit red light (wavelength: 620 nm) was formed by vapor deposition of a mixture of bis(1-phenylisoquinoline)-(acetylacetonate)iridium (III) (ADS069RE available from American Dye source) as a red phosphorous dopant and (4,4′-N,N′-dicarbazole)biphenyl (CBP) as a host material at a dopant concentration of 10%. Thereafter, a first electron-transport layer 13a was formed by vapor deposition of Alq₃.

Next, SiO₂ nanoparticles (available from Sigma-Aldrich Co. LLC., diameter; 5 to 15 nm) were uniformly dispersed on the first electron-transport layer 13a, and therefore a nanoparticle layer with the thickness of 60 nm was formed. Subsequently, onto the nanoparticle layer of SiO₂, Alq₃ used as material for a second electron-transport layer 13b was vapor-deposited. Thus, gaps between the SiO₂ particles were filled with Alq₃ and as a result of that a scattering layer 5 was formed. Additionally, the second electron-transport layer 13b was formed on the scattering layer 5. Here, the scattering layer 5 was composed of scattering particles 8 of the SiO₂ particles and layer medium 9 of Alq₃ while the second electron-transport layer 13b was formed of Alq₃. In this regard, the scattering layer 5 is present between the two electron-transport layers 13 and causes a difference in the refractive index to cause light scattering.

Thereafter, over the second electron-transport layer 13b, an electron-injection layer 14 was formed by vapor deposition of Li and a light-reflective electrode 2 (metal cathode) was formed by vapor deposition of A1.

Through the aforementioned process, an organic electroluminescence element having a configuration shown in FIG. 1 was obtained.

In Example 1, the thickness of the scattering layer 5 is 60 nm and is smaller than the red light wavelength of 620 nm. Therefore, scattering caused by the scattering layer 5 is weak scattering rather than perfect diffusion, and therefore scattering occurs while the nodes and the anti-nodes of the standing wave A caused by the light interference are kept to some extent. Besides, the positions of anti-nodes and nodes of the standing wave A and the position of the scattering layer 5 according to the structure of Example 1 are the same as those of the element shown in FIG. 1. In the configuration of Example 1, the peak of the anti-node A1 of the standing wave A arising as a result of interference is 90 nm distant from the metal cathode (light-reflective electrode 2). Therefore, the scattering layer 5 is present in such a manner that the center position C in the thickness of the scattering layer 5 is at a position 90 nm distant from the metal anode (i.e., position corresponding to the peak value).

### Comparative Example 1

In a similar manner to Example 1, over a glass substrate whose surface carries an ITO film, a hole-injection layer (PEDOT/PSS) was formed by means of application, and subsequently, a hole-transport layer (α-NPD) and a light-emitting layer to emit red light (wavelength: 620 nm) were formed. Thereafter, on the light-emitting layer to emit red light, an electron-transport layer (Alq₃) was formed by vapor deposition. In this regard, the thickness of the electron-transport layer (Alq₃) was the same as the total thickness of the first electron-transport layer 13a, the scattering layer 5, and the second electron-transport layer 13b in Example 1. Namely, the electron-transport layer was formed without forming the scattering layer 5. By using the same method as the method for Example 1 except for this, an organic electroluminescence element was obtained.

### (Evaluation 1)

Regarding each of the organic electroluminescence elements obtained by Example 1 and Comparative Example 1, frontal luminance was measured with a spectroradiometer (CS-2000). As a result, Example 1 has the frontal luminance of 580 cd/m² at a current density that allows the Comparative Example 1 to have the frontal luminance of 580 cd/m². Example 1 and Comparative Example 1 include the organic layers with the same total thickness, but the organic layer of Comparative Example 1 is devoid of the scattering layer. In summary, Example 1 has the luminance about 1.2 times higher than the luminance of Comparative Example 1. Besides, results of measurement of total luminous flux using an integrating sphere show that the total luminous flux of Example 1 is about 1.15 times greater than the total luminous flux of Comparative Example 1. Accordingly, an effect of improving the light-outcoupling efficiency was obtained.

According to Example 1, the center position C of the scattering layer 5 is at a position where the intensity of the standing wave A caused by interference of light is greatest (i.e., a position corresponding to the top (the anti-node A1) of the standing wave A). Here, Example 1 was modified such that the scattering layer 5 was displaced in the thickness direction without changing the thickness of the scattering layer 5 while the position of the side of the first electron-transport layer 13a close to the transparent electrode 1 and the position of the side of the second electron-transport layer 13b close to the light-reflective electrode 2 were not changed. When the center position C of the scattering layer 5 was at a position and the maximum intensity, at the position, of the standing wave A caused by interference of light was 90% of the peak value, the light-outcoupling efficiency was 1.15 times greater than that of Comparative Example 1. When the center position C of the scattering layer 5 was at a position where the intensity of the standing wave A caused by interference of light was constantly less than 80% of the peak value thereof, the light-outcoupling efficiency was the same as or less than that of Comparative Example 1. Consequently, it is confirmed that the center position C of the scattering layer 5 is preferably at the particular position, that is, nearby the position corresponding to a quarter of the wavelength of the standing wave A, the standing wave A being caused by interference of light. The maximum intensity of the standing wave A at the particular position is 80% or more of the peak value of the intensity of the standing wave A.

### Example 2

On a glass substrate (substrate 7) on which an ITO film had been formed as an anode (transparent electrode 1), a hole-injection layer 11 was formed by applying PEDOT/PSS thereon and making it dry. Subsequently, a first hole-transport layer 12a was formed thereon by vapor deposition of α-NPD.

Next, SiO₂ nanoparticles (available from Sigma-Aldrich Co. LLC., diameter; 5 to 15 nm) were uniformly dispersed on the first hole-transport layer 12a, and therefore a nanoparticle layer with the thickness of 60 nm was formed. Subsequently, onto the nanoparticle layer of SiO₂, α-NPD used as material for a second hole-transport layer 12b was vapor-deposited. Thus, gaps between the SiO₂ particles were filled with α-NPD, and as a result of that a scattering layer 5 was formed. Additionally, the second hole-transport layer 12b was formed on the scattering layer 5. Here, the scattering layer 5 was composed of scattering particles 8 of the SiO₂ particles and layer medium 9 of α-NPD while the second hole-transport layer 12b was formed of α-NPD. In this regard, the scattering layer 5 is present between the two hole-transport layers 12 and causes a difference in the refractive index to cause light scattering.

Thereafter, on the second hole-transport layer 12b, a light-emitting layer 3 configured to emit red light (wavelength; 620 nm) was formed by vapor-depositing a mixture of ADS069RE available from American Dye source as a red phosphorous dopant and (4,4′-N,N′-dicarbazole)biphenyl (CBP) as a host material at a dopant concentration of 10%. Then, an electron-transport layer 13 of Alq₃, an electron-injection layer 14 of Li, and a light-reflective electrode 2 (metal cathode) of A1 were formed by vapor deposition in this order.

As described above, an organic electroluminescence element having a configuration shown in FIG. 2 was obtained.

In Example 2, the thickness of the scattering layer 5 is as 60 nm and is smaller than the red light wavelength of 620 nm. Therefore, scattering caused by the scattering layer 5 is weak scattering rather than perfect diffusion, and therefore scattering occurs while the node and the anti-node of the standing wave A caused by interference are kept to an extent. Besides, the positions of anti-nodes and nodes of the standing wave A and the position of the scattering layer 5 according to the structure of Example 1 are the same as those of the element shown in FIG. 2. In the configuration of Example 2, the peak of the anti-node A1 of the standing wave A arising as a result of interference is 90 nm distant from the transparent electrode 1. Therefore, the scattering layer 5 is present in such a manner that the center position C in the thickness of the scattering layer 5 is at a position 90 nm distant from the transparent electrode (i.e., position corresponding to the peak value).

### Comparative Example 2

In a similar manner to Example 2, over a glass substrate whose surface carries an ITO film, a hole-injection layer (PEDOT/PSS) was formed by means of application, and subsequently, a hole-transport layer (α-NPD) was formed. The thickness of the hole-transport layer (α-NPD) was as the same as the total thickness of the first hole-transport layer 12a, the scattering layer 5, and the second hole-transport layer 12b in Example 2. By using the same method as the method for Example 2 except for this, an organic electroluminescence element was obtained.

### (Evaluation 2)

Regarding each of the organic electroluminescence elements obtained by Example 2 and Comparative Example 2, frontal luminance was measured with a spectroradiometer (CS-2000). As a result, Example 1 has the frontal luminance of 550 cd/m² at a current density that allows the comparative example 2 to have the frontal luminance of 500 cd/m². Example 2 and Comparative Example 2 include the organic layers with the same total thickness, but the organic layer of Comparative Example 2 is devoid of the scattering layer. In summary, Example 2 has the luminance about 1.1 times higher than the luminance of Comparative Example 2. Besides, results of measurement of total luminous flux using an integrating sphere show that the total luminous flux of Example 2 is about 1.1 times greater than the total luminous flux of Comparative Example 2. Accordingly, an effect of improving the light-outcoupling efficiency was obtained.

### Example 3

On a glass substrate (substrate 7) on which an ITO film had been formed as an anode (transparent electrode 1), a hole-injection layer 11 was formed by applying PEDOT/PSS thereon and making it dry. Subsequently, a hole-transport layer 12, a first light-emitting layer 3a to emit blue light (fluorescence, wavelength: 440 nm), a second light-emitting layer 3b to emit green light (fluorescence, wavelength: 550 nm), and a first electron-transport layer 13a were formed thereon in this order by vapor deposition of Alq₃, vapor deposition of α-NPD, co-vapor deposition of styryl-based dopant material and host material, co-vapor deposition of coumarin-based dopant material and host material, and vapor deposition of Alq₃, respectively. Consequently, a first light-emitting unit was obtained.

Thereafter, an interlayer 6 including a charge-generation layer 15 was formed. In this regard, part of the interlayer 6 served as the scattering layer 5. For preparation of the interlayer 6, first, the charge-generation layer 15 was formed on a first light-emitting unit (on the first electron-transport layer 13a) by stacking an n-type charge-transport layer and a p-type charge-transport layer in this order by vapor-deposition. Subsequently, a SiO₂ nanoparticle layer with the thickness of 60 nm was formed thereon by dispersing SiO₂ nanoparticles (available from Sigma-Aldrich Co. LLC., diameter; 5 to 15 nm) uniformly. The material of the n-type charge-transport layer was a metal-doped layer of Cs-doped2,9-dimethyl-4,7-diphenyl-1,10-phenanthroline. The material of the p-type charge-transport layer was V₂O₅ which is metal oxide. The interlayer 6 was composed of the n-type charge-transport layer, p-type charge-transport layer, and the scattering layer 5 of SiO₂.

Subsequently, a second light-emitting unit is formed on the interlayer 6. To form the second light-emitting unit, a second hole-transport layer 12b was formed by vapor deposition of α-NPD, first. In this regard, scattering properties were provided by a structure in which α-NPD was vapor-deposited on SiO₂ of the interlayer. Note that gaps between the SiO₂ nanoparticles were filled with α-NPD.

Next, a third light-emitting layer 3c to emit red light (phosphorescence, wavelength: 620 nm) was formed by vapor deposition of a mixture of bis(1-phenylisoquinoline)-(acetylacetonate)iridium (III) (ADS069RE available from American Dye source) as a red phosphorous dopant and (4,4′-N,N′-dicarbazole)biphenyl (CBP) as a host material at a dopant concentration of 10%. Thereafter, a fourth light-emitting layer 3d to emit green light (phosphorescence, wavelength: 548 nm) was formed by vapor deposition of a mixture of Bis(2-(9,9-dihexylfluorenyl)-1-pyridine)(acetylacetonate)iridium(III) (ADS078GE available from American Dye source) and (4,4′-N,N′-dicarbazole)biphenyl (CBP) as a host material at a dopant concentration of 15%. Subsequently, a first electron-transport layer 13a was formed by vapor deposition of Alq₃. Then, an electron-injection layer 14 of Li that is an alkali metal and a light-reflective electrode 2 (cathode) of aluminum were stacked.

Consequently, a multiunit organic electroluminescence element with a configuration shown in FIG. 3 was obtained.

In Example 3, the thickness of the scattering layer 5 is 60 nm and is smaller than the wavelengths of light having colors. Therefore, scattering caused by the scattering layer 5 is weak scattering rather than perfect diffusion, and therefore scattering occurs while the node and the anti-node of the standing wave A caused by the light interference are kept to some extent. Besides, according to the structure of Example 3, the scattering layer 5 is positioned in such a manner that a center position C thereof is at a particular position for each of blue light (phosphorescence) and green light (fluorescence), and the maximum intensity, at the particular position for each of blue light (phosphorescence) and green light (fluorescence), of the standing wave is 80% or more for each of blue light (phosphorescence) and green light (fluorescence) in the first light-emitting unit.

### Example 4

A multiunit organic electroluminescence element with a configuration shown in FIG. 4 was obtained by a similar manner to Example 3 except that the center position C of the scattering layer 5 was 250 nm distant from a lower surface 202 of the light-reflective electrode 2.

### Comparative Example 3

In a similar manner to Example 3, over a glass substrate whose surface carries an ITO film, a first light-emitting unit was formed. Subsequently, on the first light-emitting unit, an interlayer including a charge-generation layer was disposed. In this regard, the interlayer includes no scattering layer and the thickness of the scattering layer is the same as the interlayer 6 of Example 3. Material for the charge-generation layer is similar to that of Example 3. By using the same method as the method for Example 3 except for this, an organic electroluminescence element was obtained.

### Comparative Example 4

A multiunit organic electroluminescence element with a configuration shown in FIG. 4 was obtained by a similar manner to Example 3 except that the center position C of the scattering layer 5 was 350 nm distant from a lower surface 202 of the light-reflective electrode 2.

### (Evaluation 3)

Regarding organic electroluminescence elements obtained by Examples 3 and 4 and Comparative Examples 3 and 4, frontal luminance was measured with using a spectroradiometer (CS-2000). The results show that Comparative Example 3 has the frontal luminance of 1000 cd/m² and Comparative Example 4 has the frontal luminance of 950 cd/m². Comparative Example 3 has the organic layer with the same total thickness as that of Example 3 but is devoid of the scattering layer. Comparative Example 4 has the center position C which is 350 nm distant from the lower surface 202 of the light-reflective electrode 2. The results also show that Example 3 has the frontal luminance of 1250 cd/m² and Example 4 has the frontal luminance of 1300 cd/m². Example 3 has an effect that its luminance is about 1.25 times greater than the luminance of Comparative Example 3. Example 4 has an effect that its luminance is about 1.37 times greater than the luminance of Comparative Example 4. Besides, results of measurement of total luminous flux using an integrating sphere show that total luminous flux of Example 3 is about 1.2 times greater than the total luminous flux of Comparative Example 3, and total luminous flux of Example 4 is about 1.4 greater than Comparative Example 4. Accordingly, an effect of improving the light-coupling efficiency was obtained.

1. An organic electroluminescence element comprising:
a transparent electrode;
a light-reflective electrode; and
an organic layer including a light-emitting layer and being between the transparent electrode and the light-reflective electrode,
wherein:
the organic layer further includes a scattering layer for scattering light from the light-emitting layer;
a standing wave results from interference of the light from the light-emitting layer;
a center position of a thickness of the scattering layer is at a particular position; and
a maximum intensity of the standing wave at the particular position is 80% or more of a peak value of an intensity of the standing wave.

2. The organic electroluminescence element according to claim 1, wherein the scattering layer is between the light-emitting layer and the light-reflective electrode.

3. The organic electroluminescence element according to c aim 1, wherein the scattering layer is between the light-emitting layer and the transparent electrode.

4. The organic electroluminescence element according to claim 1, wherein:
the organic layer includes a plurality of the light-emitting layers and an interlayer between the plurality of light-emitting layers; and
the interlayer includes the scattering layer.

5. The organic electroluminescence element according to any one of claim 1, wherein
the standing wave of the light from the light-emitting layer has a node at the light-reflective electrode.

6. The organic electroluminescence element according to any one of claim 1, wherein:
the organic layer includes a green light-emitting layer and the scattering layer; and
a distance between the scattering layer and the light-reflective electrode falls within a range of 60 nm to 95 nm.

7. The organic electroluminescence element according to any one of claim 1, wherein:
the organic layer includes a green light-emitting layer and the scattering layer; and
a distance between the scattering layer and the light-reflective electrode falls within a range of 190 nm to 280 nm.
